(19) United States
(12) Patent Application Publication
(10) Pub. No.: US 2020/0146171 A1
(43) Pub. Date: May 7, 2020

(54) REMOVABLE WALL FOR A MODULAR DATA CENTER

(71) Applicant: EdgePoint Systems LLC, Dallas, TX (US)

(72) Inventor: Mohamed Aboul Fotouh, Austin, TX (US)

(73) Assignee: EdgePoint Systems LLC

(21) Appl. No.: 16/676,215

(22) Filed: Nov. 6, 2019

Related U.S. Application Data
(60) Provisional application No. 62/756,415, filed on Nov. 6, 2018.

(51) Int. Cl. H05K 7/14; E04B 1/343; E04H 9/16; E04H 5/02

(52) U.S. Cl. CPC H05K 7/1497; E04B 1/34321; H05K 7/20745; E04H 5/02; E04H 9/16

(57) ABSTRACT

A modular data center can be constructed to allow a modular data center to act alone as a data center or to be physically combined with other modular data centers to a size determined by client use cases. A fabricator can form a shell at a module assembly and factory site by assembling a floor, a roof over the floor, and two end walls connected to the floor to support the roof creating a shell opening. A removable side wall can cover the shell opening. A data center operator can remove the removable side wall from the shell opening at a data center site.

### RELATED APPLICATION

This application claims priority to and the benefit of under 35 USC 119 of U.S. provisional patent application titled “A Modular Data Center with Improvements,” filed Nov. 6, 2018, Ser. No. 62/756,415, which is incorporated herein by reference in its entirety.

### NOTICE OF COPYRIGHT

A portion of this disclosure contains material that is subject to copyright protection. The copyright owner has no objection to the facsimile reproduction by anyone of the material subject to copyright protection as it appears in the United States Patent & Trademark Office's patent file or records, but otherwise reserves all copyright rights whatsoever.

### FIELD

Embodiments of the design provided herein generally relate to a data center including a telecommunications data center. In an embodiment, a modular data center may have a removable wall to allow multiple modular data centers to be combined in, for example, a future expansion of that data center.

### BACKGROUND

Information Technology (“IT”) operations are a crucial aspect of most organizational operations in the western world. One of the main concerns is business continuity. Companies rely on their information systems to run their operations. If a system becomes unavailable, company operations may be impaired or stopped completely. It is necessary to provide a reliable infrastructure for IT operations, in order to minimize any chance of disruption. Information security is also a concern, and for this reason a datacenter has to offer a secure environment, which minimizes the chances of a security breach. A datacenter must therefore keep high standards for assuring the integrity and functionality of its hosted computer environment. Telcordia GR-3160, NEBS Requirements for Telecommunications Data Center Equipment and Spaces, provides guidelines for datacenter spaces within telecommunications networks, and environmental requirements for the equipment intended for installation in those spaces.

### SUMMARY

A data center can be constructed to allow a modular data center to act alone as a data center or to be physically combined with other modular data centers to an amount of joined and abutted modular data center determined by client use cases. A fabricator can form a shell of a modular data center at a module assembly and factory site by assembling a floor, a roof over the floor, and two end walls connected to the floor to support the roof creating a shell opening. A fabricator can mount a set of servers and other Information Technology rack equipment in the shell. A removable side wall can cover the shell opening, where the removable side wall is made of concrete and constructed to withstand winds of at least 75 miles an hour. A data center operator can remove the removable side wall from the shell opening at the data center site. The data center operator can remove the removable side wall to join and abut a second prefabricated modular data center to create a single larger data center. The modular data center provider can mount electrical infrastructure, plumbing, and HVAC to support the set of servers and other Information Technology rack equipment to the shell while avoiding attachment of this equipment to the removable side wall. Thus, removal of the removable side wall can be removed without having to shut down all data center operations.

These and other features of the design provided herein can be better understood with reference to the drawings, description, and claims, all of which form the disclosure of this patent application.

### DRAWINGS

The drawings refer to some embodiments of the design provided herein in which:

FIG. 1 illustrates a block diagram of an embodiment of an exterior of a modular data center.

FIG. 2 illustrates a block diagram of an embodiment of an interior of a modular data center.

FIG. 3 illustrates a block diagram of an embodiment of a ceiling view of a modular data center.

FIG. 4 illustrates a block diagram of an embodiment of an entry wall of a modular data center.

FIG. 5 illustrates a block diagram of an embodiment of a proposed site for a data center and a future expansion by joining additional prefabricated modular data centers.

FIG. 6 illustrates a block diagram of an embodiment of a second prefabricated modular data center, with its removable wall removed, joined and abutted with the first modular data center at the shell opening to create a single larger data center.

FIG. 7 illustrates a block diagram of an embodiment of an interior of modular data centers joined and abutted at the shell opening to create a single larger data center.

FIG. 8 illustrates a block diagram of an embodiment of an interior of a removable side wall.

FIG. 9 illustrates a block diagram of an embodiment of an exterior of a removable side wall.

FIG. 10 illustrates a block diagram of an embodiment of a supporting !-beam.

FIG. 11 illustrates a block diagram of an embodiment of a floor seam of a data center megaplex.

FIG. 12 illustrates a block diagram of an embodiment of an end wall seam of a data center megaplex.

FIG. 13 illustrates a block diagram of an embodiment of a roof seam of a data center megaplex.

FIG. 14 illustrates a flowchart of an embodiment of a method for fabricating a modular data center.

FIG. 15 illustrates a flowchart of an embodiment of a method for creating data center megaplex.

FIG. 16 illustrates a flowchart of an embodiment of a method for removing a removable side wall.

While the design is subject to various modifications, equivalents, and alternative forms, specific embodiments thereof have been shown by way of example in the drawings and will now be described in detail. It should be understood that the design is not limited to the particular embodiments disclosed, but—on the contrary—the intention is to cover all modifications, equivalents, and alternative forms using the specific embodiments.

### DESCRIPTION

In the following description, numerous specific details are set forth, such as examples of specific data signals, named components, number of servers in a system, etc., in order to provide a thorough understanding of the present design. It will be apparent, however, to one of ordinary skill in the art that the present design can be practiced without these specific details. In other instances, well known components or methods have not been described in detail but rather in a block diagram in order to avoid unnecessarily obscuring the invention. Thus, the specific details set forth are merely examples. The specific details may be varied from and still be within the spirit and scope of the invention. Example processes for and apparatuses to manage cooling for a datacenter facility are described. The following drawings and text describe various example implementations of the design.

A fabricator can build an entire data center at a module assembly and factory site as a modular data center. The fabricator can then ship that modular data center to the site of a data center. A data center operator at that site can then connect that modular data center to any power source or data transmission media available at that site of a data center. A data center operator can be a manager or agent of the manager in charge of operating the data center at the site of the data center. This provides the data center with a plug-and-play capability not normally present in this type of equipment. Depending on the needs of the data center operator, one or more modular data centers may be linked into a data center megaplex to increase computing power at the initial installation and/or in future expansions of that data center. A data center megaplex as used herein refers to a data center comprised of multiple modular data centers.

The modular data center as used herein conveys a prefabricated modular data center that ships on the road preinstalled with IT racks of computing equipment, electrical distribution system and uninterruptible power supply (UPS) batteries, and a heating/ventilation/air-conditioning (HVAC) system. Thus, a fabricator can ship a modular data center on the road as an integrated unit. The modular data center includes a prefabricated telecommunications data center or other data center that is designed in a modular fashion.

The modular data center can accommodate any design of IT computing equipment racks that include servers, databases, etc. of varying size and manufacturer. The IT computing equipment racks can have varying depths and clearances for the racks, which all can still be installed in the modular data center. The IT racks can be a heterogeneous mix of IT racks from different manufactures. As the shell structure for the modular data center is a formed concrete structure, rather than a modified rail car, the fabricator can adjust the size of the modular data center based on the size of the IT computing equipment.

The system is designed for an initial set of one or more modular data centers that may readily connect to other modular data centers at a future date of operation of the overall site via a side wall removable from the rest of the shell of the modular data center. Further, the electrical and HVAC systems acting as a data center electrical infrastructure support a maximum load of IT racks per modular data center.

The IT rack computer room, the electrical distribution room, and the HVAC system all ship as one integrated unit. There is no need to interconnect these three components in the field at the construction site because they were shipped and manufactured as an integrated unit. Note, when a modular data center ships, this unit is designed to stay below the super load limit. Thus, the modular data center is constructed to stay below the super load limit of 100,000 pounds and 12-foot width for shipping freight.

The modular data center is designed to allow the removal of one or multiple sections of a wall, or even removal of an entire wall. The modular data center is designed to allow an expansion modular data center to be placed in direct adjacency to the original modular data center. As each modular data center is made so as to interlock with other modular data centers, certain adjustments are made to the structure of the shell structure, the layout of the data center electrical infrastructure, and the design of the HVAC system to accommodate modular growth.

In the modular data center, the construction and design facilitate the removal of the concrete wall, reinforced with iron rebar and foam inserts. A data center operator may remove even merely sections of the wall at some later date past the initial construction of the modular data center without interrupting the operations of the existing IT racks in the modular data center. In removing the wall, the wall can be picked up and out of the modular data center to expand the floor space for IT racks of equipment in the future.

With the removable wall removed, a first modular data center can interconnect with a second modular data center with its removable wall removed to double the floor space for IT racks. Thus, the IT racks of servers from the initial modular data center are integrated with the server racks from the expansion modular data center on the same data floor. In addition, a third or more modular data centers may interconnect with other modular data centers with the removable wall or just sections of removable wall removed to combine floor space for IT racks in connected modular data centers.

The removable wall is made of a concrete base with limited attachments to the shell of the modular data center, as well as any internal data center infrastructure and equipment mountings, in order to make the wall easily removable. Each wall has a connection point to allow the wall to be lifted and set in place by an industrial device. For example, the wall can have one or more forklift cutouts to receive the prongs of a forklift. Alternately, the wall can have a crane hook attachment to interface with a crane. Also, the walls can be connected via bolts and brackets that can be loosened to allow the wall to be removed, as opposed to using concrete anchors to secure the wall to the other walls and foundation of a modular data center. Thus, in an embodiment, both side walls can be constructed as removable walls made of concrete with connection points for large object handling machinery. The side walls can be secured in place by brackets and bolts.

Also, no critical infrastructure runs along the side of the removable wall. No panels or other structures are mounted to the removable wall. Instead, any panels and structures are mounted to the shell, comprising the two fixed side walls, the floor, or the ceiling. This leaves the removable wall with no critical structure attached to the removable wall, rendering the wall more readily removable.

The pipes and electrical conduit are supported by connections to the floor, ceiling, or the other two fixed walls. Thus, the support structures for the equipment and infrastructure are supported from shell, and not from either of the removable walls of the modular data center.

The modular data center can use steel reinforced concrete walls and ceilings, and concrete or cinder block floors verses steel shipping containers. The features for each reinforced wall, such as the filter space and air plenum, are cast in place during fabrication. The removable wall is designed to allow expansion of the IT rack space in the future, and to have no permanent attachments to other equipment in the modular data center to that removable wall as a support structure for that equipment installed in the modular data center.

The air containment system includes one or more HVAC units coupled to the concrete sidewalls of the modular data center, an air filter frame, air plenums cast in the concrete sidewalls, a free air flow design through the aisles of the modular data center, and a dividing wall. The containment air supply, air conditioning, and air-cooling system divide up the hot and cold aisles. A dividing wall in the shell acts as an air dam to separate hot and cold air plenums in the building. The air containment system with the dividing wall provides a barrier between the hot and cold air plenums in the container building. The HVAC units specifically work with the dividing wall to return hot air thorough the sidewalls of the shell on one side of the wall and supply cold air through the sidewall of the other side of the wall.

An HVAC cooling unit couples to the side wall of the containment building. The HVAC units are specifically configured structurally to work with the wall to supply air on the rear and suck air on the front. Thus, the system does not supply air to the bottom of the container and then suck returned hot air from the top of the container building. The HVAC cooling units are built and constructed to match the air flow pattern for supplying the free-flowing air into the cold aisle of the data floor and sucking hot free flowing air from the hot aisle of the data floor. The HVAC unit is built with multiple compartments. One compartment uses positive pressure to blow cooled free flowing air. The other compartment uses negative pressure to suck the hot air and route the hot air into the compressor to cool that air.

Again, the HVAC cooling unit couples to the side wall of the containment building. The frame that supports the supply and return filters can be built into the sidewalls. Also, this HVAC unit does not use ducting to direct the flow of air through the modular data center. Rather, the HVAC unit uses free flowing air to blow in the cold air from the sidewall. The HVAC unit then uses the dividing wall to act as a damper separator. The HVAC unit then returns the hot air through the free flow of air to the sidewall on the return side.

A fabricator may assemble a modular data center at the module assembly and factory site. The fabricator can mount a set of servers and other Information Technology rack equipment in the modular data center at the module assembly and factory site. The fabricator may ship the modular data center to a data center operator at a site of the data center. The data center operator can then operate the set of servers and other Information Technology rack equipment as a data center in modular data center at the site of the data center. If a single modular data center does not provide enough computing power for the data center operator's needs, the data center operator can connect the modular data center with an expansion modular data center to create a data center megaplex of merged modular data centers at the site of the data center.

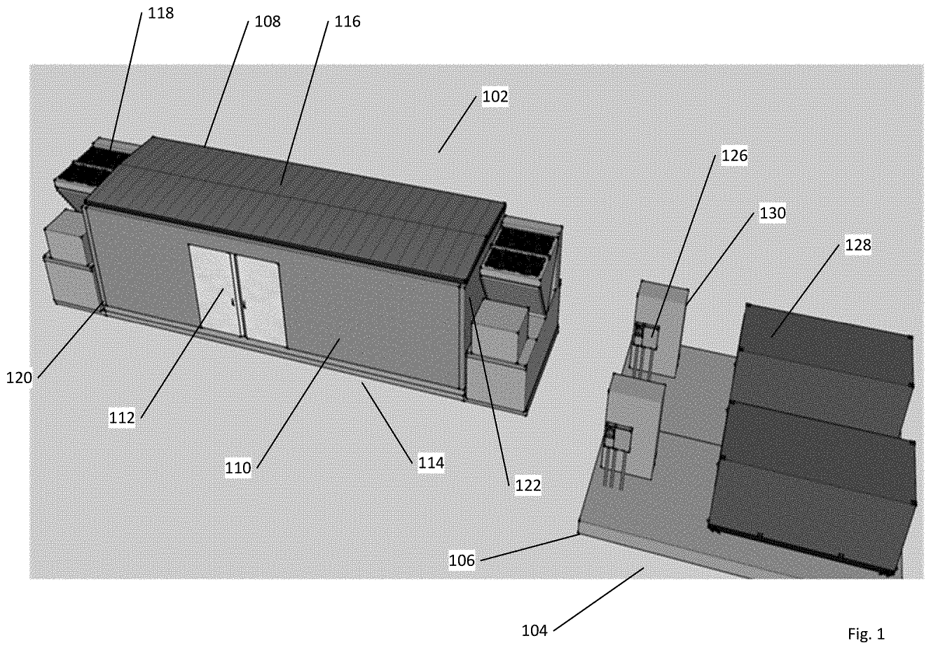

FIG. 1 illustrates a block diagram of an embodiment of an exterior of a single modular data center. The modular data center can have a containment building 102 to contain the set of servers and other Information Technology rack equipment that perform various data and communications operations. The modular data center can have a power center 104 to manage the power supply to the data center. The power center 104 can be mounted to the containment building 102 or established near the containment building on a concrete skid 106.

The containment building 102 may have a pre-cast concrete shell 108 with a front wall 110. The front wall 110 may have a door 112 to access the containment building 102. The concrete shell 108 may be rated to withstand winds exceeding 150 miles per hour. The concrete shell 108 may have a floor 114, a roof 116 over the floor 114, and two end walls connected to the floor, creating a shell opening. A HVAC unit 118 can be mounted to an end wall acting as a cooling source 120. The HVAC unit 118 may provide enough cooling to support double the number of servers and other Information Technology rack equipment in the data server set. The other end wall near the power center acts as a power source wall 122.

The power center 104 may have a utility meter 126 to measure incoming power consumed and provide a point of disconnect in a time of emergency. The power center 104 may have a backup generator 128 to provide power during a power failure. The power center 104 may have an automatic transfer switchgear 130 to switch from an exterior power source to the backup generator 128.

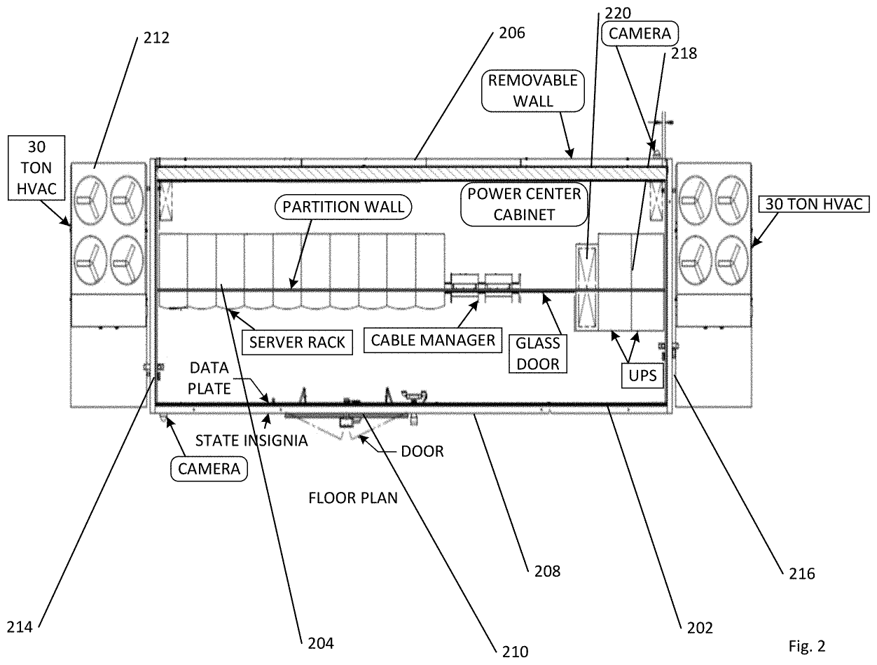

FIG. 2 illustrates a block diagram of an embodiment of an interior of a modular data center. The concrete shell 202 may contain a set of servers and other Information Technology rack equipment 204 mounted to the floor in the shell 202 to perform data center operations.

The shell 202 may have a shell opening created by the floor, two end walls, and the roof. A removable side wall 206 may cover the shell opening. The removable side wall 206 can be attached to the shell 202 via a structural connector. The removable side wall 208 may be a rear wall opposite a front entry wall 208. The front entry wall 208 may have a door 210 for entering the modular data center.

The removable side wall 206 can be i) constructed to span the shell opening with a concrete wall and ii) constructed with securing mechanisms to secure to at least to the two end walls while still being capable of being removed from the shell opening at the site of the data center by unsecuring the securing mechanisms. The removable side wall 206 also has a lifting mechanism built into the concrete wall to allow removal of the removable side wall at the site of the data center in order to allow a second prefabricated modular data center, with its removable wall removed, to be joined and abutted with the modular data center at the shell opening to create a single larger data center.

The shell 202 may have an end wall acting as a cooling source wall 212. The cooling source wall 212 may have a HVAC unit 214 mounted to the cooling source wall 214 to control the air temperature of the modular data center. The shell 202 may have an end wall acting as a power source wall 216. The power source wall 216 may have a power unit 218 mounted to the power source wall 216 to act as an uninterruptible power source. The power unit 218 may direct power through a power center cabinet 220 to provide a control system for the power unit 218.

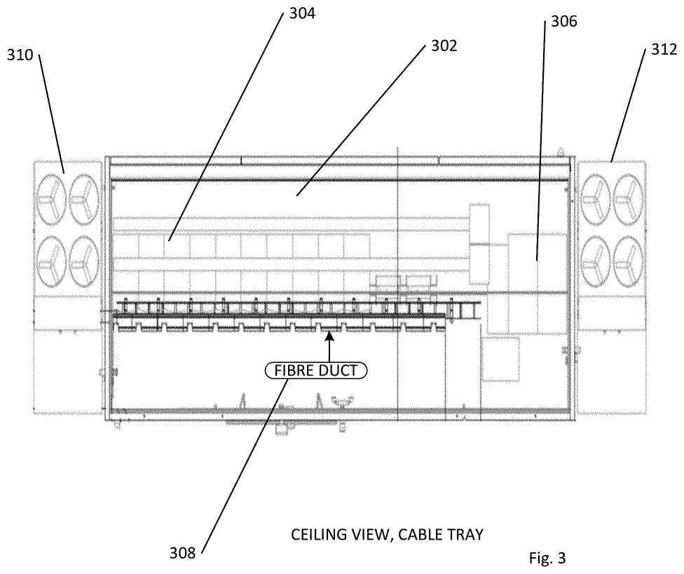

FIG. 3 illustrates a block diagram of an embodiment of a ceiling view of a modular data center. The modular data center may have a roof 302 to shelter the set of servers and other Information Technology rack equipment 304. The modular data center may have a power unit 306 to supply power for the set of servers and other Information Technology rack equipment 304. The modular data center may have a fiber duct 308 along the ceiling or the floor to connect the set of servers and other Information Technology rack equipment 304 to the power unit 306. The modular data center 302 may have a HVAC unit 310 to control the air temperature and humidity of the modular data center 302. The modular data center 302 may have a backup HVAC unit 312 should the primary HVAC unit 310 fail.

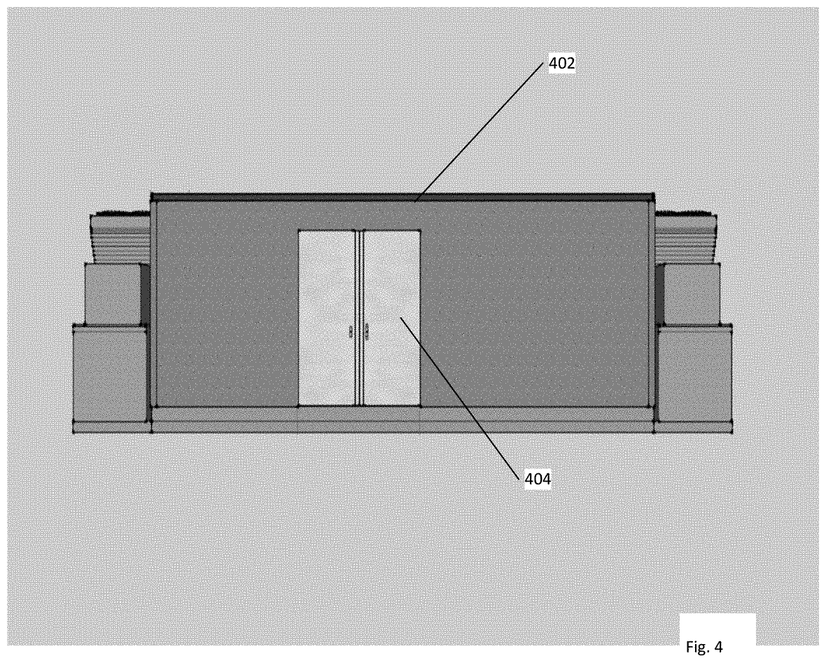

FIG. 4 illustrates a block diagram of an embodiment of an entry wall of a modular data center. The modular data center may have an entry wall 402 with a door 404 to allow access to the modular data center. Generally, the rear wall is to be the wall removed when combining modules. If a third module is being added, then a data center operator can remove the entry wall 402 to connect the original modular data center to a rear shell opening for the third modular data center.

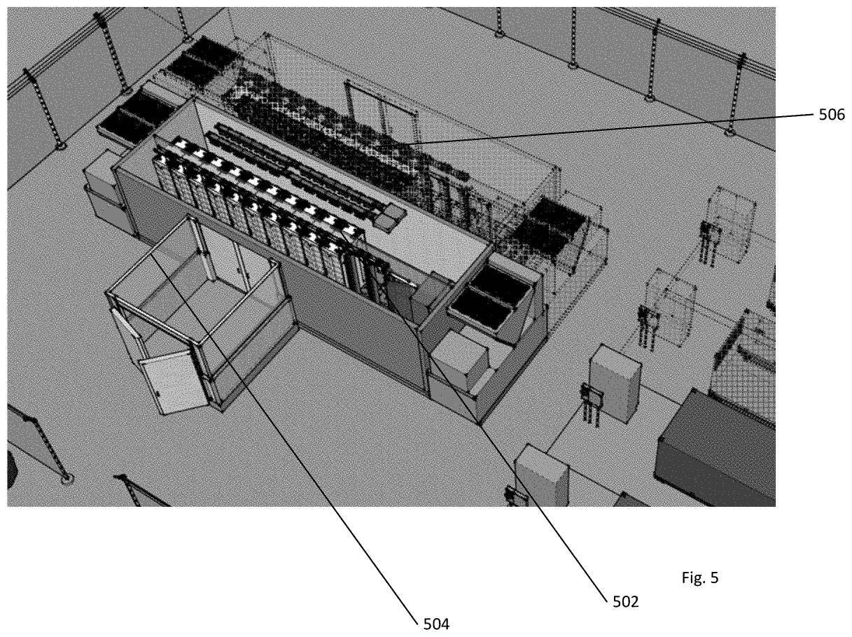

FIG. 5 illustrates a block diagram of an embodiment of a proposed site for a data center and a future expansion by joining additional prefabricated modular data centers. The site of the data center can have a modular data center 502 to perform data center operations. The data center operator can erect a vestibule 504 around the door of the modular data center 502 to act as decontamination point before entering the modular data center 502. The data center operator can clear a location next the modular data center 502 to set an expansion modular data center 506.

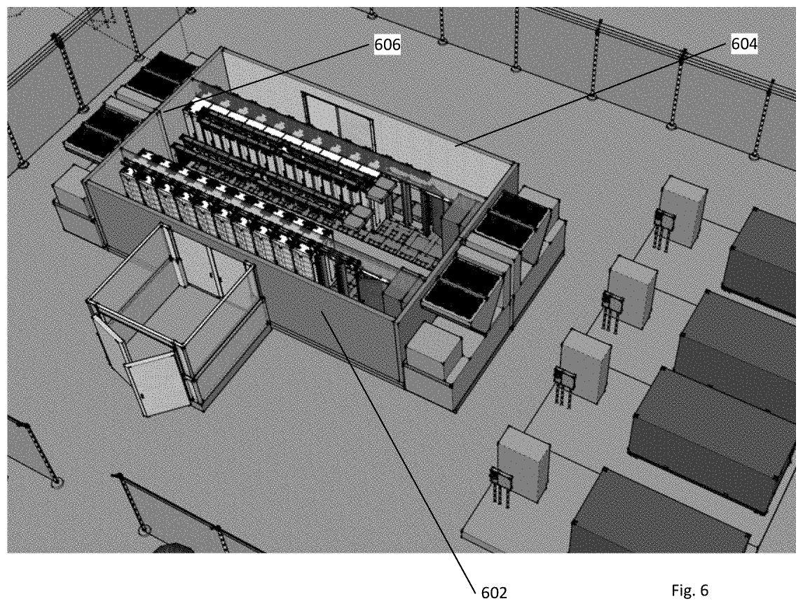

FIG. 6 illustrates a block diagram of an embodiment of a data center and a future expansion by joining additional prefabricated modular data centers. The data center operator can remove the removable rear wall from a modular data center 602. The data center operator can remove the removable rear wall from an extension modular data center 604. The data center operator can line the shell opening of the modular data center 602 with the shell opening of the expansion modular data center 604. The data center operator can then connect the modular data center 602 to the expansion modular data center 604. FIG. 6 illustrates a seam 606 where the removable wall sections from the modular data center 602 and the expansion modular data center 604 have been removed and replaced by this thin seam 606 between modular data center 602 and the expansion modular data center 604. The removable walls would have run in between the two sets of servers and other IT rack equipment.

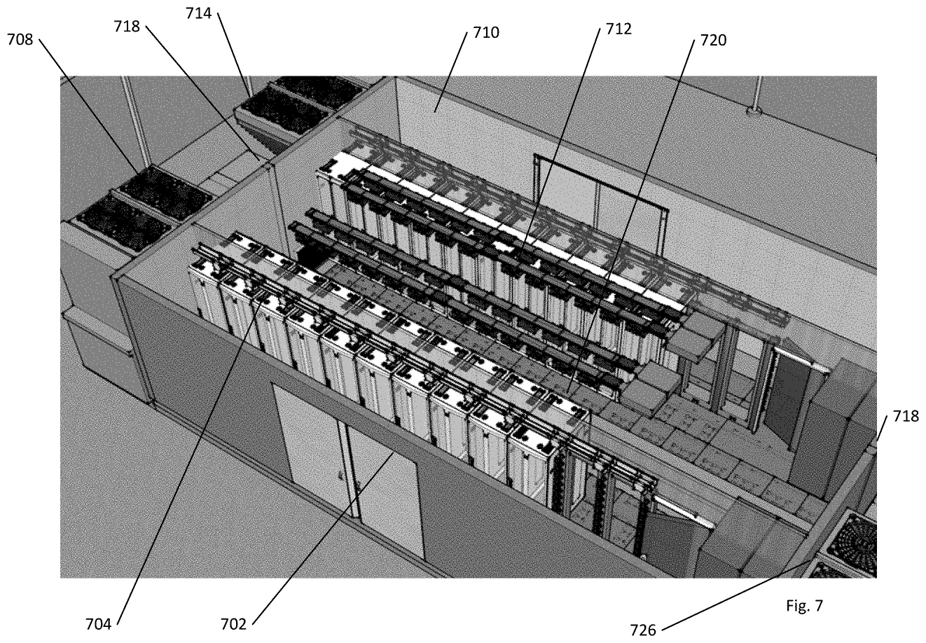

FIG. 7 illustrates a block diagram of an embodiment of an interior of modular data centers joined and abutted at the shell opening to create a single larger data center. An initial modular data center 702 may have an initial set of servers and other Information Technology rack equipment 704 of one or more data servers. The modular data center 702 may have a power unit 708 to supply power for the set of servers and other Information Technology rack equipment 704. The power unit 708 has the capacity to power twice the number of data servers in the set of servers and other Information Technology rack equipment 704. The modular data center 702 may have a HVAC unit 708 to control the air temperature and humidity of the modular data center 702. The HVAC unit 726 has the capacity to cool twice the number of data servers in the set of servers and other Information Technology rack equipment 704.

An expansion modular data center 710 may have an expansion server set 712 of one or more data servers and/or other Information Technology rack equipment. The expansion modular data center 710 may have an expansion power unit 714 to supply power for the expansion data server set 712. The expansion power unit 714 has the capacity to power twice the number of data servers in the expansion server set 712. The expansion modular data center 710 may have an expansion HVAC unit to control the air temperature and humidity of the expansion modular data center 710. The expansion HVAC unit has the capacity to cool twice the number of servers and racks in the expansion server set 712.

The data center operator may align the shell opening of the modular data center 702 with the shell opening of the expansion modular data center 710. The data center operator may caulk the two end walls of the modular data center 702 to the two end walls of the expansion modular data center 710 to create two end wall seams 718. The data center operator may apply flashing to the two end wall seams 718. The data center operator may connect the floor of the shell of the modular data center 702 to the floor of the expansion modular data center to create a floor seam 720. The data center operator can create the floor seam 720 by bolting a steel skid of the floors together. Alternately, the data center operator can create the floor seam 720 by welding the steel skid of the floors together.

FIG. 7 illustrates the wall seams 718 where the removable wall sections from the modular data center 702 and the expansion modular data center 710 have been removed and replaced by this thin seam 718 between modular data center 702 and the expansion modular data center 710.

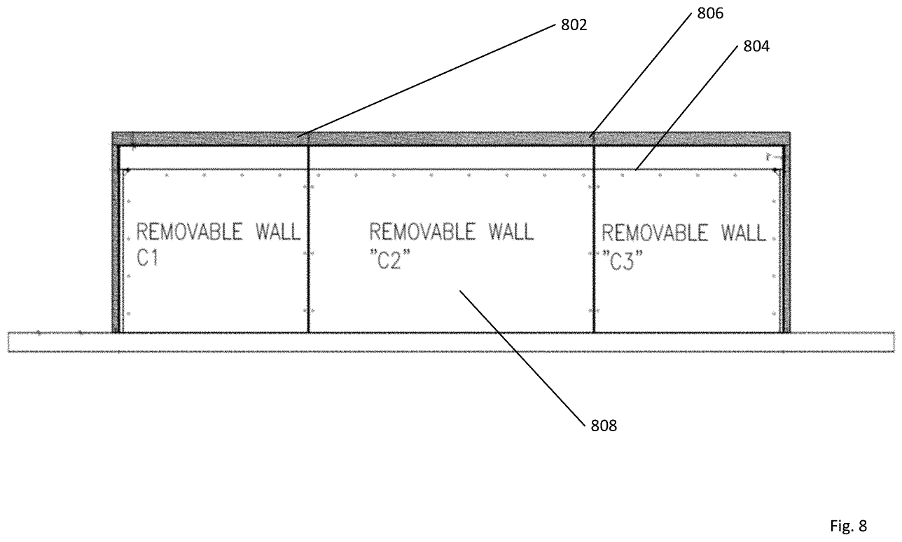

FIG. 8 illustrates a block diagram of an embodiment of an interior of a removable side wall. The fabricator can form the removable side wall with at least four-and-a-half-inch thick concrete to form an external wall of modular data center capable of withstanding hurricane force winds. The fabricator may include metal rebar in the concrete to improve the strength of the removable side wall 802. The fabricator may include foam inserts in the concrete to reduce the weight of the removable side wall 802. The removable side wall 802 may be divided into two or more panels 804 to improve ease of handling. The removable side wall 802 can be constructed as segments of wall panels and includes at least two wall panels. The fabricator may apply a caulked sealant to the seam 806 between each panel 804 once the panels have been attached to the structural connectors of the shell. The fabricator may apply a weather barrier 808 to the interior of the removable wall 802 to provide additionally protection to the interior of the modular data center.

Note, each wall panel has its own lifting mechanism built into that wall panel. The lifting mechanism built into the concrete wall of the removable wall 802 can be at least one forklift cutout in the concrete wall to facilitate handling during removal of the removable wall at the site of the data center in order to allow the second prefabricated modular data center, with its removable wall removed, to be joined and abutted with the modular data center at the shell opening.

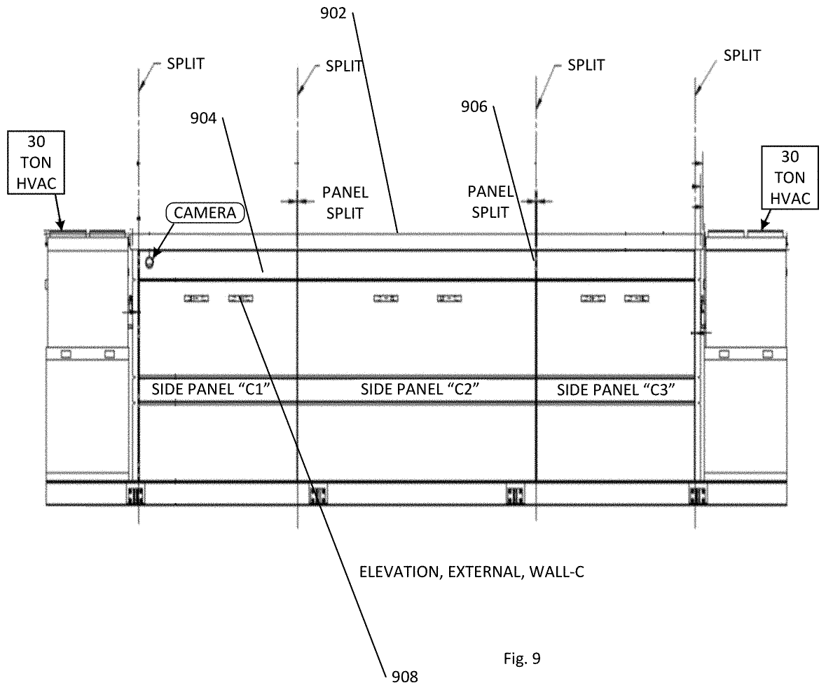

FIG. 9 illustrates a block diagram of an embodiment of an exterior of a removable side wall. As discussed, the removable side wall 902 may be divided into at least two panels 904 to improve ease of handling. The fabricator may apply a caulked sealant to the seam 906 between each panel 904 once the panels have been attached to the structural connectors of the shell. The fabricator may form one or more forklift cutouts 908 into the removable wall to allow a forklift to easily lift and remove the side wall 902. The fabricator may apply grout to the forklift cutout 908 to hide the forklift cutout 908 from casual observers.

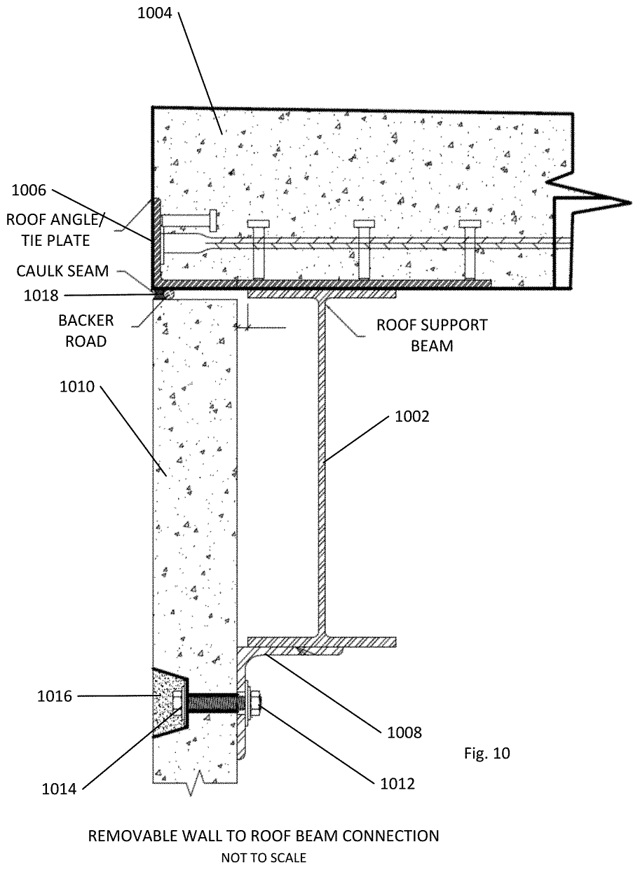

FIG. 10 illustrates a block diagram of an embodiment of a supporting !-beam. The modular data center may use a steel I-beam 1002 to provide the support normally provided by a wall to the two end walls as they support the roof 1004. The !-beam 1002 mounted between the two end walls to support the two end walls and a weight of the roof 1004 so that the removable side wall can be removed to form the shell opening in the shell of the modular data center. The fabricator may weld the !-beam 1002 to a tie plate 1006 screwed into the roof 1004 of the modular data center. The fabricator may weld a bracket 1008 to the I-beam 1002 to act as a structural connector to the removable side wall 1010 and the roof and end walls of the shell. The fabricator may screw a nut 1012 and bolt 1014 through the removable side wall 1010 and bracket 1008 via a pocket former molded 1016 into the removable side wall 1010. The fabricator may cover the pocket former 1016 with grout after the side wall has been connected. The fabricator may then apply a caulk seal 1018 to the gap between the removable side wall 1010 and the roof 1004.

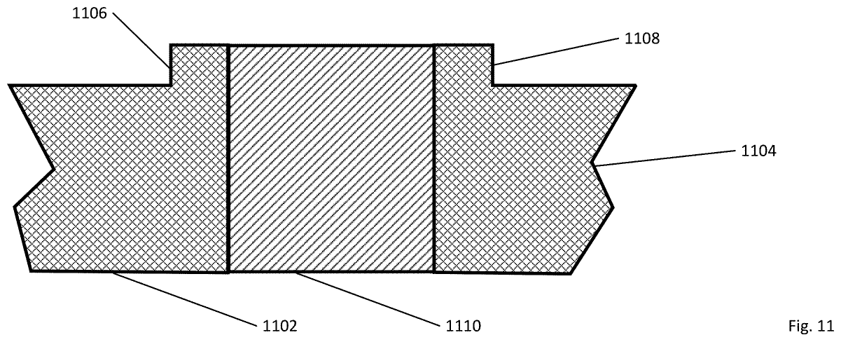

FIG. 11 illustrates a block diagram of an embodiment of a floor seam of a data center megaplex. The data center operator can align an initial floor 1102 of the initial modular data center with the expansion floor 1104 of the expansion modular data center. The data center operator can connect the initial floor 1102 to the expansion floor 1104 of the second prefabricated modular data center, with its removable wall removed, via at least one of i) bolting ii) welding, and iii) any combination of bolting and welding at a steel skid portion the floor. For example, the data center operator can create a welding 1106 between a steel skid 1108 of the initial floor 1102 and a steel skid 1110 of the expansion floor 1104. Alternately, the data center operator can bolt the initial skid 1108 to the expansion skid 1110.

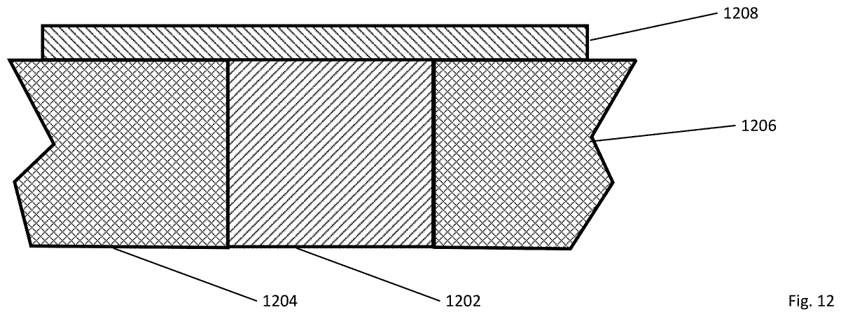

FIG. 12 illustrates a block diagram of an embodiment of an end wall seam of a data center megaplex. A data center operator can caulk 1202 an end wall 1204 of the initial modular data center to an end wall 1206 of the expansion modular data center to create an end wall seam. The data center operator can apply flashing 1208 to cover the end wall seam.

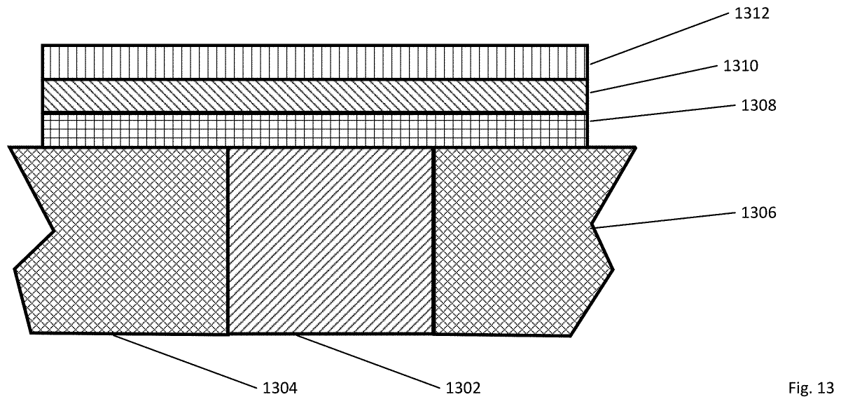

FIG. 13 illustrates a block diagram of an embodiment of a roof seam of a data center megaplex. A data center operator can caulk 1302 a roof 1304 of the initial modular data center to a roof 1306 of the expansion modular data center to create a roof seam. The data center operator can cover the roof seam with a membrane 1308 to protect from the weather. The data center operator can cover the roof seam and the membrane 1308 with flashing 1310. The data center operator can apply roofing material 1312 to the flashing 1310.

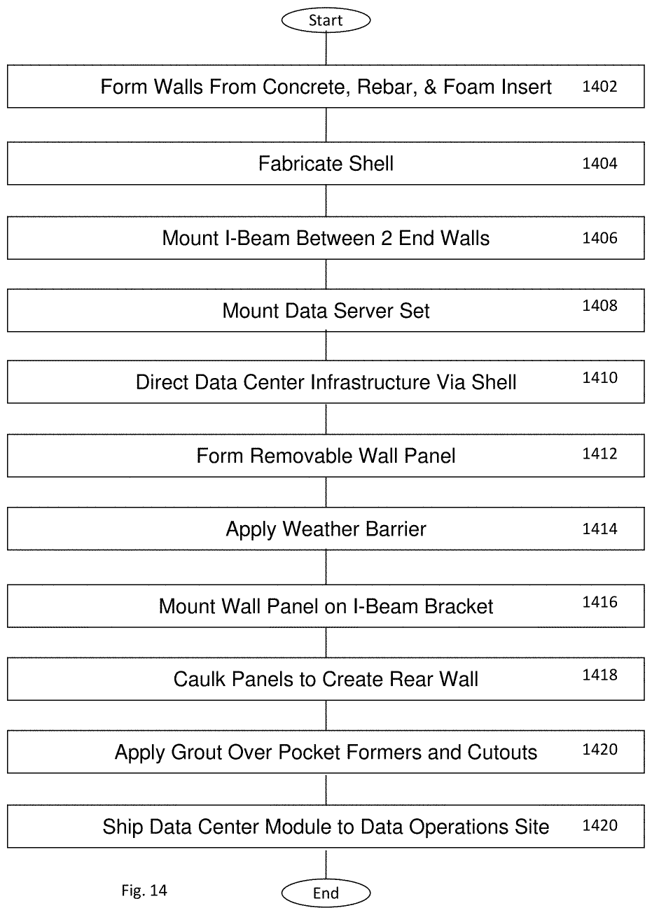

FIG. 14 illustrates a flowchart of an embodiment of a method for fabricating a modular data center. A fabricator can form the walls of the containment structure from concrete with an internal structure having metal rebar for structure support and foam inserts to reduce the weight of the structure (Block 1402). The fabricator can fabricate a shell of a prefabricated modular data center at a module assembly and factory site from a floor, a roof over the floor, and two end walls connected to the floor to support the roof to create a shell opening (Block 1404). The fabricator can mount a steel I-beam between the two end walls for support (Block 1406). The fabricator can mount a data server set of one or more data servers to a data server mounting structure on an interior of the shell (Block 1408). The fabricator can install and route electrical infrastructure, piping, and any HVAC via the shell (Block 1410). The data center electrical infrastructure may include wiring, power conduits, data conduits, and other electrical gear transmitting electricity or data to and from the data server set and any controls and environmental controllers. The data center electrical infrastructure has no attachment to the removable side wall. Thus, the electrical infrastructure and any piping to support at least the set of servers and other Information Technology rack equipment is 1) not on or secured to the removable side wall 2) but rather secured to any of the floor, the roof, and the two end walls of the shell so that removal of the removable side wall can be performed without having to shut down the servers and other Information Technology rack equipment.

The fabricator can form the removable side wall from concrete as panels with a four-and-a-half-inch thickness (Block 1412). The removable side wall can have an internal structure of metal rebar for structure support and foam inserts to reduce the weight of the removable wall. The fabricator can apply a weather barrier to the interior of the panels of the removable side wall to cover any forklift cutouts (Block 1414). The fabricator can mount the panels of the removable side wall to the shell by bolting the panels via pocket forms to a bracket mounted to the I-beam (Block 1416). The fabricator can apply caulk sealant between the panels to create the rear wall of the containment structure (Block 1418). The fabricator can apply grout over the pocket forms and any forklift cutouts in the walls (Block 1420). The fabricator can then ship the modular data center from the module assembly and factory site to the site of the data center (Block 1422).

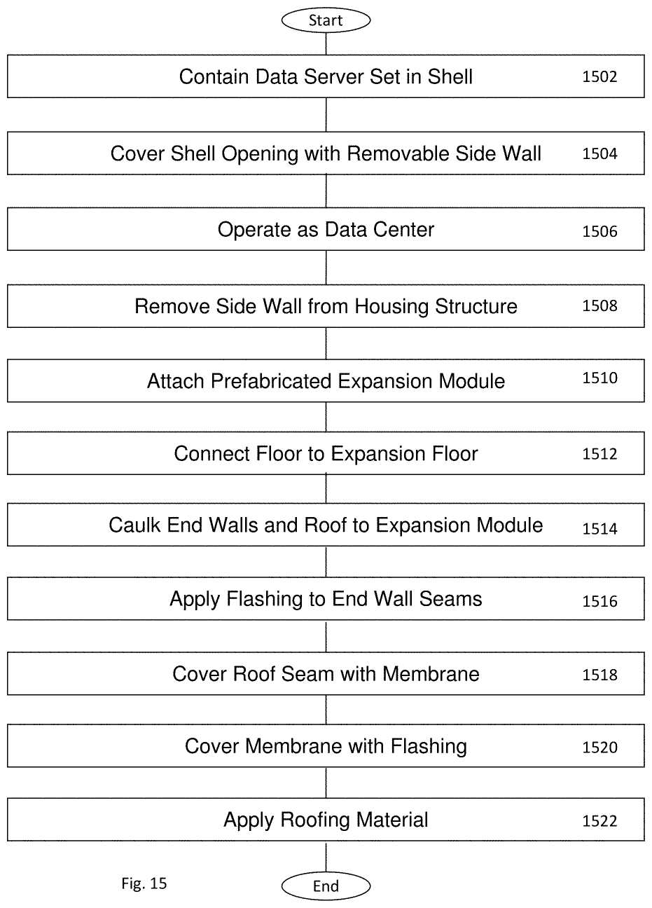

FIG. 15 illustrates a flowchart of an embodiment of a method for creating data center megaplex. The modular data center can contain a data server set of one or more data servers in a shell of a modular data center fabricated at a module assembly and factory site (1502). The shell has a floor, a roof over the floor, two end walls connected to the floor to support the roof, and an I-beam to support the two end walls. The floor, the roof, and the two end walls create a shell opening. The modular data center covers the shell opening with a removable side wall (Block 1504). The data center operator can operate the set of servers and other Information Technology rack equipment as a data center in the modular data center at a site of the data center (Block 1506).

If the data center operator decides to expand the data center, the data center operator can remove the removable side wall from the shell at the site of the data center (Block 1508). The data center operator can attach a prefabricated expansion modular data center to the shell opening to create a data center megaplex of merged modular data centers at the site of the data center (Block 1510). The data center operator can connect the floor of the shell to a floor of the prefabricated expansion modular data center via at least one of bolting and welding at a steel skid of the floor (Block 1512). The data center operator can caulk the two end walls of the prefabricated expansion date center module to create two end wall seams and the roof to a roof of the prefabricated expansion modular data center to create a roof seam (Block 1514). The data center operator can apply flashing to cover the two end wall seams (Block 1516). The data center operator can cover the roof seam with a membrane to protect from the weather (Block 1518). The data center operator can cover the roof seam and the membrane with flashing (Block 1520). The data center operator can apply roofing material to the flashing on the roof seam (Block 1522).

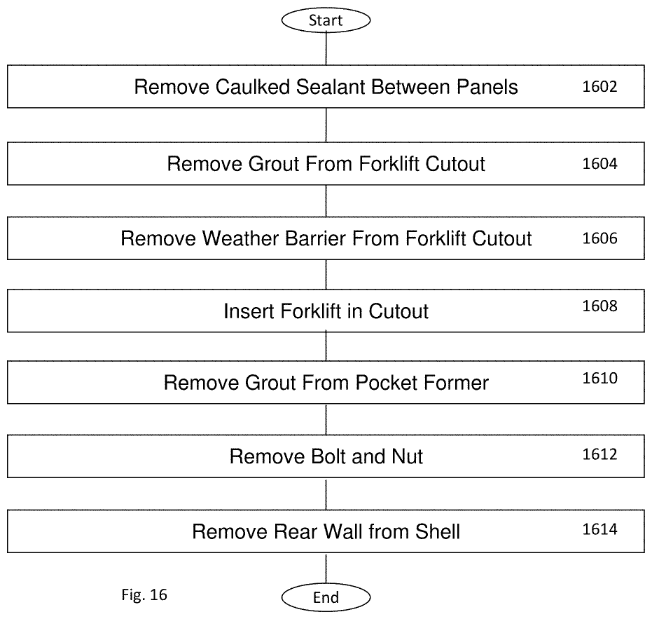

FIG. 16 illustrates a flowchart of an embodiment of a method for removing a removable side wall. The data center operator can remove caulked sealant from between two or more panels forming the removable side wall (Block 1602). The data center operator can remove grout from an exterior side of at least one forklift cutout (Block 1604). The data center operator can remove a weather barrier from an interior side of the at least one forklift cutout (Block 1606). The data center operator can insert a forklift into at least one forklift cutout in the removable side wall to lift the removable side wall (Block 1608). The data center operator can remove grout from covering on an exterior side of the removable side wall at least one pocket former containing at least one bolt and nut connecting the removable side wall to the shell (Block 1610). The data center operator can remove the at least one bolt and nut to disconnect the removable side wall (Block 1612). The data center operator can then use the forklift to remove the removable side wall from the shell of the modular data center (Block 1614).

While some specific embodiments of the design have been shown, the design is not to be limited to these embodiments. The design is to be understood as not limited by the specific embodiments described herein, but only by the scope of the appended claims. Moreover, specific components and various embodiments have been shown and described. It should be understood that the invention covers any combination, sub-combination, or re-combination, including duplicating components, subtracting components, combination components, integrating components, separating components, and/or dividing components.

The terms “approximately” and “about” are used interchangeably to indicate that the disclosed and suggested values do not require exact precision. The relative inclusions of values around each value depends on the error in building, manufacturing, and installing the components, as is generally practiced by a person of skill in the art. Even without the specific identification of approximation (i.e. the term “about” or “approximate”), all of the dimensions disclosed are examples only and include equivalent or approximate values to the stated value to achieve similar, equal, or better benefits or effects to those of the disclosed dimensions. “Majority” is understood to be more than 50% of the floor area, while “substantial” is understood to be at least more than 75% of the floor and preferably more than 85% of the floor area.

What is claimed is:

1. A prefabricated modular data center, comprising:
a shell of the modular data center formed at a module assembly and factory site by assembling at least a floor, a roof over the floor, and two end walls connected to the floor and roof to support the roof to create a shell opening, where the modular data center, as assembled, is shippable to a site of a data center as an integrated unit;
a set of servers and other Information Technology rack equipment mounted to the floor in the shell;
a removable side wall i) constructed to span the shell opening with a concrete wall and ii) constructed with securing mechanisms to secure to at least to the two end walls while still being capable of being removed from the shell opening at the site of the data center by unsecuring the securing mechanisms, where the removable side wall also has a lifting mechanism built into the concrete wall to allow removal of the removable side wall at the site of the data center in order to allow a second prefabricated modular data center, with its removable wall removed, to be joined and abutted with the modular data center at the shell opening to create a single larger data center; and
where electrical infrastructure and any piping to support at least the set of servers and other Information Technology rack equipment is 1) not secured to the removable side wall 2) but rather secured to any of the floor, the roof, and the two end walls of the shell so that removal of the removable side wall can be performed without having to shut down the servers and other Information Technology rack equipment.

2. The prefabricated modular data center of claim 1, further comprising:
an I-beam mounted between the two end walls to support the two end walls and a weight of the roof so that the removable side wall can be removed to form the shell opening in the shell of the modular data center.

3. The prefabricated modular data center of claim 2, further comprising:
a bracket mounted to the I-beam to act as a structural connector between the removable side wall and the roof and end walls of the shell.

4. The prefabricated modular data center of claim 3, further comprising:
at least one pocket former on an exterior side of the removable side wall to insert a bolt and a nut to connect the removable side wall to the structural connector.

5. The prefabricated modular data center of claim 1, further comprising:
where the lifting mechanism built into the concrete wall of the removable wall is at least one forklift cutout in the concrete wall to facilitate handling during removal of the removable wall at the site of the data center in order to allow the second prefabricated modular data center, with its removable wall removed, to be joined and abutted with the modular data center at the shell opening.

6. The prefabricated modular data center of claim 1, wherein the removable side wall is constructed as segments of wall panels and includes at least two wall panels, where each wall panel has its own lifting mechanism built into that wall panel.

7. The prefabricated modular data center of claim 1, wherein the shell and the removable side wall are formed from concrete with one or more internal structures that additionally include any of a metal rebar insert and a foam insert.

8. The prefabricated modular data center of claim 1, wherein the removable side wall is made of at least four-and-a-half-inch thick concrete to form an external wall of modular data center capable of withstanding hurricane force winds.

9. A method for a modular data center, comprising:
shipping a set of servers and other Information Technology rack equipment mounted in a shell of a modular data center to a site of a data center as an integrated unit, where the modular data center has a floor, a roof over the floor, two end walls connected to the floor to support the roof, and an I-beam supporting the two end walls, which is all assembled at a module assembly and factory site;
covering a shell opening created by the floor, the roof, and the two end walls in the modular data center with a removable side wall; where the removable side wall was i) constructed to span the shell opening with a concrete wall and ii) constructed with securing mechanisms to secure to at least to the two end walls while still being capable of being removed from the shell opening at the site of the data center by unsecuring the securing mechanisms, where the removable side wall also has a lifting mechanism built into the concrete wall to allow removal of the removable side wall at the site of the data center in order to allow a second prefabricated modular data center, with its removable wall removed, to be joined and abutted with the modular data center at the shell opening to create a single larger data center.

10. The method of claim 9, further comprising:
removing the removable side wall from the shell at the site of the data center; and
attaching a second modular data center at the shell opening to create an integrated data center of merged modular data centers at the site of the data center.

11. The method of claim 9, further comprising:
removing grout from covering on an exterior side of the removable side wall at least one pocket former containing at least one bolt and nut connecting the removable side wall to the shell, where the at least one pocket former containing at least one bolt and nut connecting the removable side wall to the shell form the securing mechanism; and
removing the at least one bolt and nut to disconnect the removable side wall from an end wall of the shell.

12. The method of claim 9, further comprising:
removing grout on an exterior side from at least one forklift cutout in the removable side wall and a weather barrier from an interior side of the at least one forklift cutout, where the forklift cutout forms the lifting mechanism built into the concrete wall to allow removal of the removable side wall at the site of the data center; and
inserting a forklift into the at least one forklift cutout in the removable side wall to lift the removable side wall.

13. The method of claim 9, further comprising:
connecting the floor of the shell to a floor of the second prefabricated modular data center, with its removable wall removed, via at least one of i) bolting ii) welding, and iii) any combination of bolting and welding at a steel skid portion the floor.

14. The method of claim 9, further comprising:
caulking the two end walls of the modular data center to two end walls of the second modular data center to create two end wall seams; and
applying flashing to cover the two end wall seams in order to create the single larger data center.

15. The method of claim 9, further comprising:
caulking the roof of the modular data center to a roof of the second modular data center to create a roof seam;
covering the roof seam with a membrane;
covering the roof seam and the membrane with flashing; and
applying roofing material to the flashing.

16. A method for a prefabricated modular data center, comprising:
fabricating a shell of the modular data center at a module assembly and factory site by assembling at least a floor, a roof over the floor, and two end walls connected to the floor and roof to support the roof to create a shell opening, where the modular data center, as assembled, is shippable to a site of a data center as an integrated unit;
installing a set of servers and other Information Technology rack equipment mounted on the floor in the shell; and
installing a removable side wall i) constructed to span the shell opening with a concrete wall and ii) constructed with securing mechanisms to secure to at least to the two end walls while still being capable of being removed from the shell opening at the site of the data center by unsecuring the securing mechanisms, where the removable side wall also has a lifting mechanism built into the concrete wall to allow removal of the removable side wall at the site of the data center.

17. The method of claim 16, further comprising:
installing electrical infrastructure and any piping to support at least the set of servers and other Information Technology rack equipment 1) not on or secured to the removable side wall 2) but rather secured to any of the floor, the roof, and the two end walls of the shell so that removal of the removable side wall can be performed on the data center without having to shut down the servers and other Information Technology rack equipment.

18. The method of claim 16, further comprising:
installing an I-beam mounted between the two end walls to support the two end walls and a weight of the roof so that the removable side wall can be removed to form the shell opening in the shell of the modular data center.

19. The method of claim 16, further comprising:
creating a pocket former on an exterior side of the removable side wall to insert a bolt and a nut to connect the removable side wall to a support connecting to the I-beam.

20. The method of claim 16,
installing the removable side wall as segments of wall panels that includes at least two wall panels, where each wall panel has its own lifting mechanism built into that wall panel.
